(19) United States
(12) Patent Application Publication
(10) Pub. No.: US 2007/0202661 A1
(43) Pub. Date: Aug. 30, 2007

(54) Semiconductor substrate, production method thereof and semiconductor device

(75) Inventors: Hiromichi Kinpara, Toyota-shi (JP); Kazuhiko Katami, Toyota-shi (JP); Toru Onishi, Nagoya-shi (JP); Hideki Tojima, Numazu-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Toyota Jidosha Kabushiki Kaisha

(21) Appl. No.: 11/705,124

(22) Filed: Feb. 12, 2007

(30) Foreign Application Priority Data
Feb. 14, 2006 (JP) 2006-36438

(51) Int. Cl. H01L 21/76

(52) U.S. Cl. 438/424; 257/E21.545

(57) ABSTRACT

[Problem to be Solved] An object is to provide an art for preventing an element formative layer (active layer) from peeling off from a buried insulating film (intermediate insulating layer) with regard to production method of a semiconductor substrate having trench construction.

[ Solution ] Production method of a semiconductor substrate, constructed by laminating a support substrate 53, a buried insulating film 52 and an element formative layer 51 in this order and having a trench 56 in the element formative layer 51 for separating an element, comprises a process forming one or plural trenches 56 in the element formative layer 51 along an outer perimeter of an element formative area E so as to connect the element formative area E of the element formative layer 51 to an outer peripheral part thereof at a part thereof at least; a process oxidizing a part of the element formative layer 51 connecting the element formative area E to the outer peripheral part thereof; and a process filling up the trenches 56 with an insulator, thereby forming the trenches 56 in the element formative layer 51 so as to make the element formative area E not independent.

### THE TECHNICAL FIELD TO WHICH THE INVENTION BELONGS

The present invention relates to an art of a semiconductor substrate having trenches for separating elements, production method thereof, and a semiconductor device. Particularly, the present invention relates to an art for preventing an element formative layer (active layer) from peeling off from a buried insulating film (intermediate insulating layer), each of them constituting the semiconductor substrate.

### DESCRIPTION OF THE PRIOR ART

Conventionally, there is well known trench structure as one of arts for separating elements of a semiconductor substrate. A so-called SOI wafer having a buried insulating film (intermediate insulating layer) is used as a substrate wafer, and trenches are formed between elements so as to reach the buried insulating film. Accordingly, the elements are separated from each other perfectly by insulator, whereby the elements are prevented from interfering with each other.

As a production method of a semiconductor substrate having the above-mentioned trench structure, for example, there is a method described in the Patent Literature 1.

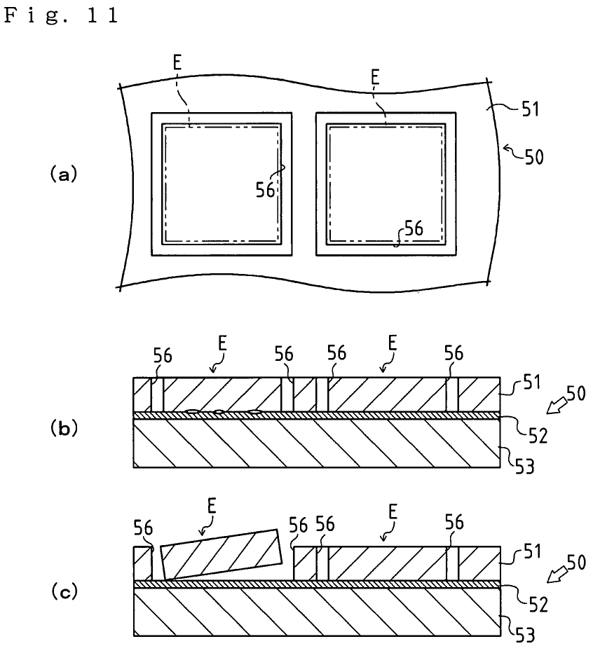

FIG. 10 is a drawing explaining the flow of production of the conventional semiconductor substrate. FIG. 11 is a plan view of the conventional semiconductor substrate.

Firstly, with regard to a SOI wafer 50 comprising an element formative layer 51, a buried insulating film 52 and a support substrate 53, a trench mask 55 is formed in the element formative layer 51 while parts at which trenches are formed are not masked (FIG. 10a). Then, the parts of the element formative layer 51 not masked by the trench mask 55 are removed by etching so as to form the trenches 56 (FIG. 10b). The trench mask 55 is removed (FIG. 10c) and then the trenches 56 are oxidized thermally so as to form an oxide film 57 on the side wall of each of the trenches 56 (FIG. 10d). Subsequently, an insulator 58 such as polycrystalline silicon is accumulated on the trenches 56 by CVD or the like so as to fill the trenches 56 (FIG. 10e). Finally, the insulator 58 and the trench mask 55 on the upper layer are removed by etching, whereby the semiconductor substrate having the trench structure is completed (FIG. 10f).

However, if the trenches 56 are formed by the above-mentioned production method, the element formative layer 51 is divided into independent pieces. Normally, as shown in FIGS. 11a and 11b, each of the trenches 56 is formed in the element formative layer 51 along a perimeter of element formative area E in which the element is formed, whereby each of the pieces of the element formative layer 51 is independent. In this case, if a part exists which cohesive strength between the element formative layer 51 and the buried insulating film 52 is weak, the piece of the element formative layer 51 may be peeled off as shown in FIG. 11c. In addition, if void or dust exists between the element formative layer 51 and the buried insulating film 52, the cohesive strength between the element formative layer 51 and the buried insulating film 52 becomes weak.

[Patent Literature 1] the Japanese Patent Laid Open Gazette Hei. 9-74132

### SUMMARY OF THE INVENTION

### Problem to be Solved by the Invention

The present invention provides an art for preventing an element formative layer (active layer) from peeling off from a buried insulating film (intermediate insulating layer) with regard to production method of a semiconductor substrate having trench construction.

### Means for Solving the Problems

The above-mentioned problems are solved by the following means according to the present invention.

As specified in Claim 1, production method of a semiconductor substrate, constructed by laminating a support substrate, a buried insulating film and an element formative layer in this order and having a trench in the element formative layer for separating an element, comprises a process forming one or plural trenches in the element formative layer along an outer perimeter of an element formative area so as to connect the element formative area of the element formative layer to an outer peripheral part thereof at a part thereof at least; a process oxidizing a part of the element formative layer connecting the element formative area to the outer peripheral part thereof; and a process filling up the trenches with an insulator.

As specified in Claim 2, the trenches are enough deep to reach the buried insulating film, and are provided intermittently while a fixed distance exists between each two trenches adjacent to each other.

As specified in Claim 3, the fixed distance between the trenches is not less than 0.1 μm and not more than 1 μm.

As specified in Claim 4, the trenches are provided continuously along the outer perimeter of the element formative area while a fixed distance exists between the bottom surface of each of the trenches and the buried insulating film.

As specified in Claim 5, the fixed distance between the bottom surface of each of the trenches and the buried insulating film is not less than 0.1 μm and not more than 0.5 μm.

As specified in Claim 6, a semiconductor substrate, constructed by laminating a support substrate, a buried insulating film and an element formative layer in this order and having a trench in the element formative layer for separating an element, comprises one or plural trenches formed in the element formative layer so as to connect an element formative area of the element formative layer to an outer peripheral part thereof at a part thereof at least.

As specified in Claim 7, the trenches are enough deep to reach the buried insulating film, and are provided intermittently while a fixed distance exists between each two trenches adjacent to each other.

As specified in Claim 8, the fixed distance between the trenches is not less than 0.1 μm and not more than 1 μm.

As specified in Claim 9, the trenches are provided continuously along the outer perimeter of the element formative area while a fixed distance exists between the bottom surface of each of the trenches and the buried insulating film.

As specified in Claim 10, the fixed distance between the bottom surface of each of the trenches and the buried insulating film is not less than 0.1 μm and not more than 0.5 μm.

As specified in Claim 11, a semiconductor device comprises the semiconductor substrate as set forth in one of claims 6 to 10.

### EFFECT OF THE INVENTION

The present invention constructed as the above brings the following effects.

Since the element formative areas of the element formative layer are connected to each other so as not to be independent, each element formative area of the element formative layer stuck to the buried insulating film are suppressed to peel off from the buried insulating film independently. Namely, even if any void or dust exists between the element formative layer and the buried insulating film, each element formative area E of the part of the element formative layer is prevented from peeling off from the buried insulating film independently. Therefore, in the producing step of the semiconductor substrate having the trench structure, the element formative layer (active layer) is prevented from peeling off from the buried insulating film (intermediate insulating layer).

### THE BEST MODE OF EMBODIMENT OF THE INVENTION

A best embodiment of the present invention will be explained with reference to the accompanying drawings for understanding of the present invention.

FIG. 1 is a sectional side view of a SOI wafer concerning an embodiment of the present invention.

With regard to a production method of a semiconductor substrate concerning each embodiment of the present invention described below, as shown in FIG. 1, a SOI wafer 50 is constructed by laminating a support substrate 53 comprising silicon, a buried insulating film 52 as an intermediate insulating layer comprising an oxide film, and an element formative layer 51 as an active layer comprising silicon in this order. By the SOI wafer 50, a perfect dielectric separation type semiconductor substrate having trenches 56 on the element formative layer 51 is produced.

### Embodiment 1

Explanation will be given on a production method of a semiconductor substrate concerning the Embodiment 1 of the present invention.

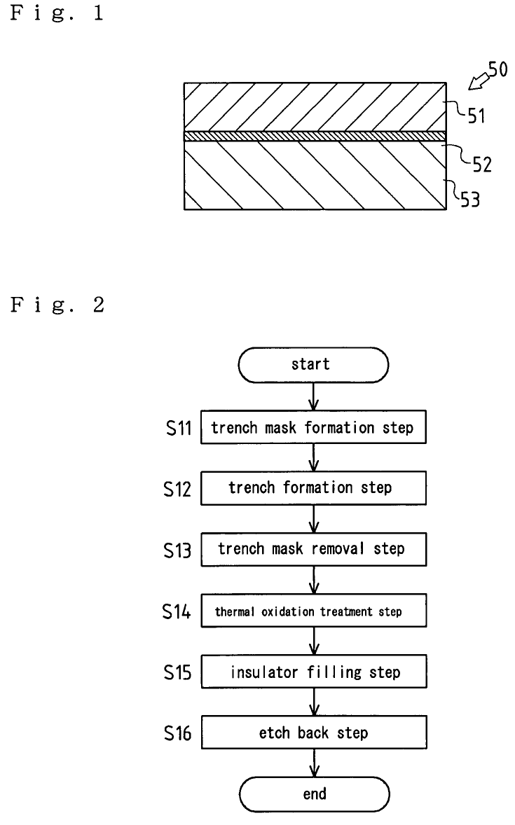

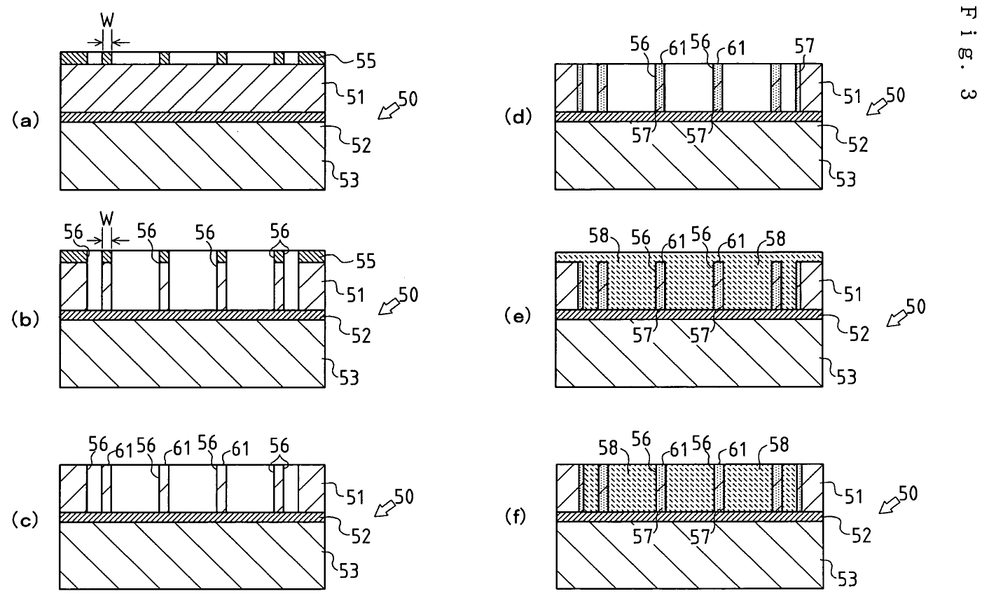

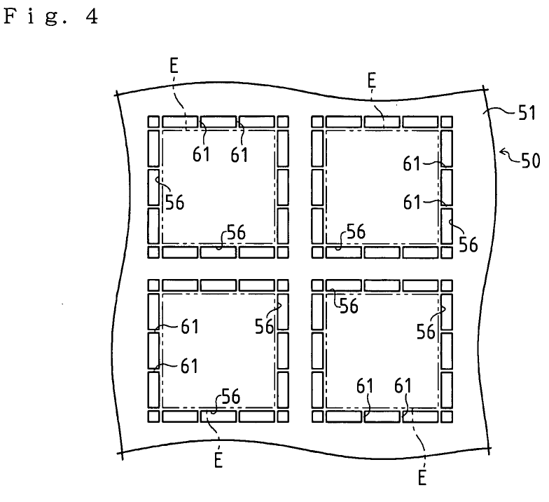

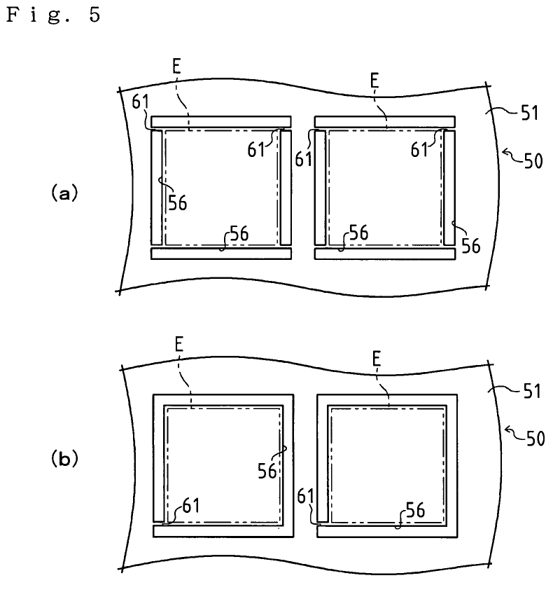

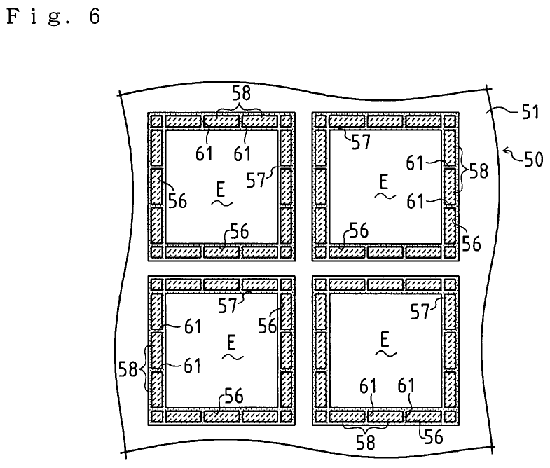

FIG. 2 is a flow chart of production of a semiconductor substrate concerning an embodiment of the present invention. FIG. 3 is a drawing explaining the flow of production of the semiconductor substrate according to the Embodiment 1. FIG. 4 is a plan view of trench pattern. FIG. 5 is a plan view of another trench pattern. FIG. 6 is a plan view of the semiconductor substrate.

Hereinafter, explanation will be given on a flow of production of a semiconductor substrate according to FIG. 2.

Firstly, as shown in FIG. 3a, a trench mask 55 is formed in the element formative layer 51 of the SOI wafer 50 (trench mask formation step S11).

The trench mask 55 has a pattern so that parts of the element formative layer 51 in which the trenches 56 (grooves) are formed are exposed and parts thereof on which elements are formed are covered.

For example, as a method for forming the trench mask 55, a photolithography method may be adopted so as to form the trench mask 55 comprising a photoresist film. Otherwise, the trench mask 55 may comprises a NSG (non-dope silica glass).

After forming the trench mask 55, as shown in FIG. 3b, the parts of the element formative layer 51 not covered by the trench mask 55 are etched to the buried insulating film 52 so that the trenches 56 are formed in the element formative layer 51 (trench formation step S12).

As a method of etching, for example, reactive ion etching which is a kind of dry etching or wet etching may be adopted.

The areas in which independent elements of the element formative layer 51 are formed are referred to as element formative areas E. The outer peripheral part of each of the element formative areas E is the part of the element formative layer 51 outside the trenches 56. As shown in FIG. 4, the trenches 56 formed as mentioned above are formed along the outer perimeter of the element formative area E while connection parts 61 connecting the element formative area E with the outer peripheral part of the element formative area E are secured at a part thereof at least.

Namely, the trenches 56 are formed so that each of the element formative areas E of the part of the element formative layer 51 and the outer peripheral part thereof are connected to each other at a part thereof at least through the element formative layer 51 (the connection parts 61).

By making each of the element formative areas E of the element formative layer 51 not independent, each of the element formative areas E of the element formative layer 51 stuck to the buried insulating film 52 are suppressed to peel off from the buried insulating film 52 independently. Accordingly, even if any void or dust exists between the element formative layer 51 and the buried insulating film 52, each of the element formative areas E of the part of the element formative layer 51 is prevented from peeling off from the buried insulating film 52 independently. Therefore, in the producing step of the semiconductor substrate having the trench structure, the element formative layer 51 is prevented from peeling off from the buried insulating film 52.

As an example of the construction that each of the element formative areas E of the part of the element formative layer 51 and the outer peripheral part thereof are connected to each other at a part thereof at least, as shown in FIG. 4, each of the trenches 56 is short belt-shaped and the bottom thereof reaches the buried insulating film 52, and the trenches 56 are arranged along the outer perimeter of the element formative area E intermittently while a fixed distance exists between each two trenches 56 adjacent to each other.

The part of the element formative layer 51 remaining between the two trenches 56 adjacent to each other is the connection part 61 which connects the element formative area E of the element formative layer 51 to the outer peripheral part of the element formative area E. In this case, the trenches 56 and the connection parts 61 are provided by turns along the outer perimeter of the element formative area E.

The distance between the two trenches 56 adjacent to each other, that is, the length W of the connection part 61 is preferably not less than 0.1 μm and not more than 1 μm (see FIG. 3a and 3b).

That is because too long treatment time is required for thermal oxidation of the connection part 61 in later-discussed thermal oxidation step if the distance between the two trenches 56 adjacent to each other is more than 1 μm.

If the distance between the two trenches 56 adjacent to each other is less than 0.1 μm, the etching treatment of the element formative layer 51 becomes difficult (the etching treatment becomes to require high accuracy), and the strength necessary to keep the element formative area E being connected to the element formative layer 51 cannot be obtained.

However, each of the element formative areas E of the element formative layer 51 is necessary only not to be independent. Accordingly, as shown in FIGS. 5a and 5b, it may alternatively constructed so that the trench 56 making nearly a round of the outer perimeter of the element formative area E is formed and at least one part of the trench 56 is divided by the connection part 61.

After forming the trenches 56 in the element formative layer 51 as mentioned above, the trench mask 55 is removed as shown in FIG. 3c (trench mask removal step S13).

As an example of method for removing the trench mask 55, for example, wet etching may be adopted.

Subsequently, as shown in FIG. 3d, thermal oxidation treatment is performed so as to oxidize the side wall of each trench 56 and each connection part 61 formed in the element formative layer 51 (thermal oxidation treatment step S14).

In this case, the side wall of each trench 56 is oxidized with the depth from 500 nm to 2 μm. Accordingly, silicon forming the connection part 61 between the trenches 56 is oxidized and becomes a thermal oxide film, whereby the connection part 61 functions as an insulating film (insulating layer). Namely, the connection part 61 functions both as an insulating film and as a member connecting the element formative area E to the outer peripheral part thereof.

Next, as shown in FIG. 3e, each of the trenches 56 is filled up with an insulator 58 (insulator filling step S15).

The insulator 58 may be polycrystalline silicon with which the trenches 56 is filled up by LPCVD, silicon oxide or silicon nitride with which the trenches 56 is filled up by plasma CVD, or NSG (non-dope silica glass) or PSG (phosphorus glass) with which the trenches 56 is filled up by atmospheric pressure CVD.

Finally, excessive insulator 58 on the outer layer is removed by etching (etch back step S16). Then, as shown in FIGS. 3f and 6, the semiconductor substrate having the perfect dielectric separation type trench structure that each of the element formative areas E is insulated perfectly from each other is obtained.

Namely, in the semiconductor substrate, each of the element formative areas E of the element formative layer 51 is insulated perfectly from each other by an insulating layer comprising the insulator 58 with which the trenches 56 is filled up, the connection part 61 as the insulating film, and the buried insulating film 52.

In addition, with regard to the semiconductor substrate constructed as mentioned above, elements such as transistors and diodes are formed in the element formative areas E of the element formative layer 51, and wires and protective films are formed, whereby the semiconductor device is completed.

In addition, the semiconductor substrate may be installed into various semiconductor devices.

### Embodiment 2

Explanation will be given on a production method of a semiconductor substrate concerning the Embodiment 2 of the present invention.

FIG. 2 is a flow chart of production of a semiconductor substrate concerning an embodiment of the present invention.

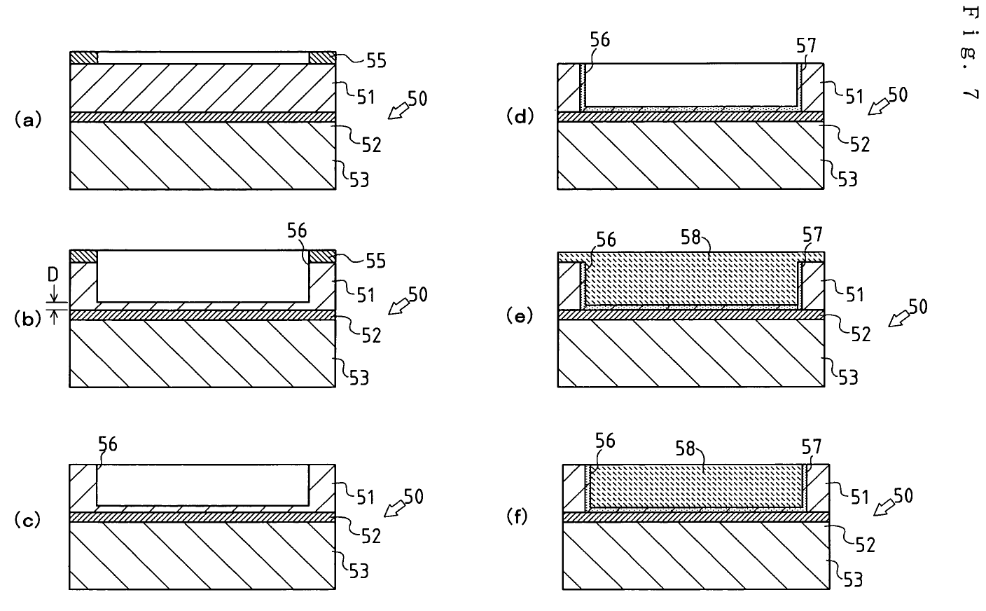

FIG. 7 is a drawing explaining the flow of production of the semiconductor substrate according to the Embodiment 2.

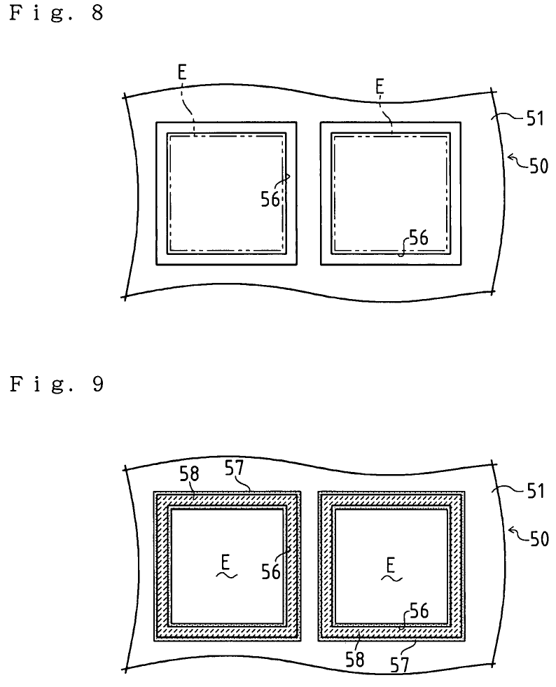

FIG. 8 is a plan view of the trench pattern.

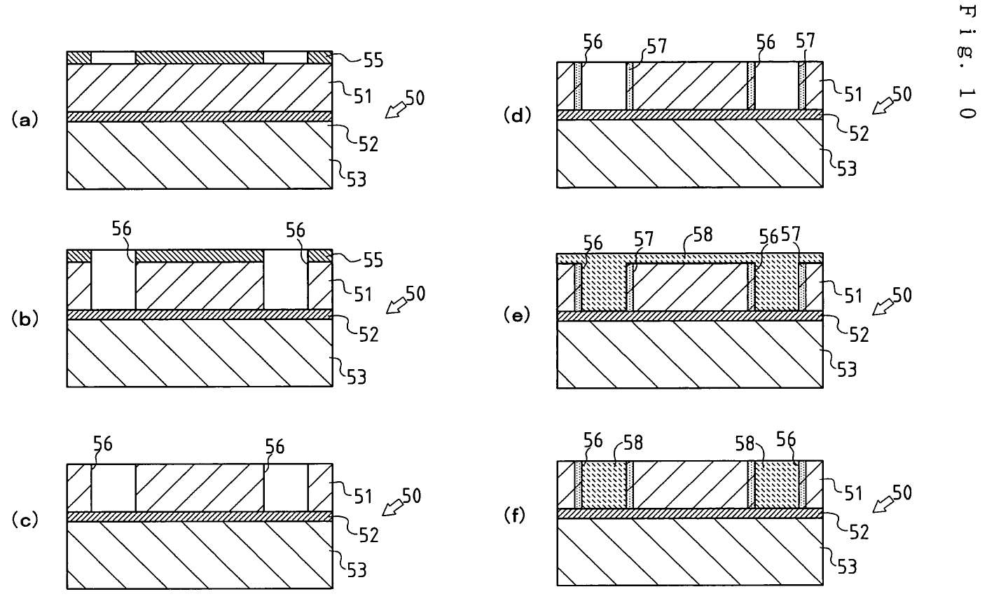

FIG. 9 is a plan view of the semiconductor substrate.

Hereinafter, explanation will be given on a flow of production of a semiconductor substrate according to FIG. 2.

In addition, later-discussed trench mask formation step S11, trench formation step S12, trench mask removal step S13, thermal oxidation treatment step S14, insulator filling step S15 and etch back step S16 are similar to the flow of production of the semiconductor substrate mentioned in the Embodiment 1, and so detailed explanation thereof is omitted.

Firstly, as shown in FIG. 7a, the trench mask 55 is formed on the element formative layer 51 of the SOI wafer 50 (trench mask formation step S11).

After forming the trench mask 55, as shown in FIG. 7b, the parts of the element formative layer 51 not covered by the trench mask 55 are etched to the buried insulating film 52 so that the trenches 56 are formed in the element formative layer 51 (trench formation step S12).

In addition, as shown in FIGS. 7b and 8, the trenches 56 are provided continuously along the outer perimeter of the element formative area E, and a fixed distance D exists between the bottom surface of each of the trenches 56 and the buried insulating film 52. Namely, the bottom surface of each of the trenches 56 does not reach the buried insulating film 52.

The element formative layer 51 remaining between the bottom surface of each of the trenches 56 and the buried insulating film 52 is the connection part which connects the element formative area E to the outer peripheral part of the element formative area E (the part of the element formative layer 51 outside the trenches 56). By providing the connection part, each of the element formative area E of the element formative layer 51 is connected to the outer peripheral part of the element formative area E so as not to be independent.

In addition, the distance D between the bottom surface of each of the trenches 56 and the buried insulating film 52 is preferably not less than 0.1 μm and not more than 0.5 μm.

That is because too long treatment time is required for thermal oxidation of the connection part 61 in later-discussed thermal oxidation step if the distance D between the bottom surface of each of the trenches 56 and the buried insulating film 52 is more than 0.5 μm.

If the distance D between the bottom surface of each of the trenches 56 and the buried insulating film 52 is less than 0.1 μm, the etching treatment of the element formative layer 51 becomes difficult (the etching treatment becomes to require high accuracy), and the strength necessary to keep the element formative area E being connected to the element formative layer 51 cannot be obtained.

By connecting each of the element formative areas E of the element formative layer 51 by the element formative layer 51 remaining between the bottom surface of each of the trenches 56 and the buried insulating film 52, each of the element formative areas E of the element formative layer 51 stuck to the buried insulating film 52 are suppressed to peel off from the buried insulating film 52 independently. Accordingly, even if any void or dust exists between the element formative layer 51 and the buried insulating film 52, each of the element formative areas E of the part of the element formative layer 51 is prevented from peeling off from the buried insulating film 52 independently. Therefore, in the producing step of the semiconductor substrate having the trench structure, the element formative layer 51 is prevented from peeling off from the buried insulating film 52.

After forming the trenches 56 in the element formative layer 51 as mentioned above, the trench mask 55 is removed as shown in FIG. 7c (trench mask removal step S13).

Subsequently, as shown in FIG. 7d, thermal oxidation treatment is performed so as to oxidize the side wall of each trench 56 and each connection part 61 formed in the element formative layer 51 (thermal oxidation treatment step S14).

In this case, the side wall and bottom surface of each of the trenches 56 are oxidized with the depth from 500 nm to 2 μm. Accordingly, silicon forming the connection part 61 between the bottom surface of each of the trenches 56 and the buried insulating film 52 is oxidized and becomes a thermal oxide film, whereby the connection part 61 functions as an insulating film (insulating layer).

Namely, the trenches 56 are formed between the element formative area E of the element formative layer 51 and the outer peripheral part thereof so that the element formative area E and the outer peripheral part thereof are connected to each other at a part thereof at least through the insulating layer. The element formative layer 51 between the bottom surface of each of the trenches 56 and the buried insulating film 52, which is the connection part between the element formative area E and the outer peripheral part thereof, functions both as an insulating film and as a member connecting the element formative area E to the outer peripheral part thereof.

Next, as shown in FIG. 7e, each of the trenches 56 is filled up with an insulator 58 (insulator filling step S15).

Finally, excessive insulator 58 on the outer layer is removed by etching (etch back step S16). Then, as shown in FIGS. 7f and 9, the semiconductor substrate having the perfect dielectric separation type trench structure that each of the element formative areas E is insulated perfectly from each other is obtained.

Namely, in the semiconductor substrate, each of the element formative areas E of the element formative layer 51 is insulated perfectly from each other by an insulating layer comprising the insulator 58 with which the trenches 56 is filled up, the connection part 61 as the insulating film, and the buried insulating film 52.

With regard to the semiconductor substrate constructed as mentioned above, elements such as transistors and diodes are formed in the element formative areas E of the element formative layer 51, and wires and protective films are formed, whereby the semiconductor device is completed.

In addition, the semiconductor substrate may be installed into various semiconductor devices.

### BRIEF DESCRIPTION OF THE DRAWINGS

[FIG. 1] It is a sectional side view of a SOI wafer concerning an embodiment of the present invention.

[FIG. 2] It is a flow chart of production of a semiconductor substrate concerning an embodiment of the present invention.

[FIG. 3] It is a drawing explaining the flow of production of the semiconductor substrate according to the Embodiment 1.

[FIG. 4] It is a plan view of trench pattern.

[FIG. 5] It is a plan view of another trench pattern.

[FIG. 6] It is a plan view of the semiconductor substrate.

[FIG. 7] It is a drawing explaining the flow of production of the semiconductor substrate according to the Embodiment 2.

[FIG. 8] It is a plan view of the trench pattern.

[FIG. 9] It is a plan view of the semiconductor substrate.

[FIG. 10] It is a drawing explaining the flow of production of the conventional semiconductor substrate.

[FIG. 11] It is a plan view of the conventional semiconductor substrate.

### DESCRIPTION OF NOTATIONS

50 a SOI wafer
51 an element formative layer
52 a buried insulating film
53 a support substrate
55 a trench mask
56 trenches
57 an oxide film
58 an insulator

1. Production method of a semiconductor substrate constructed by laminating a support substrate, a buried insulating film and an element formative layer in this order and having a trench in the element formative layer for separating an element, comprising:
a process forming one or plural trenches in the element formative layer along an outer perimeter of an element formative area so as to connect the element formative area of the element formative layer to an outer peripheral part thereof at a part thereof at least;
a process oxidizing a part of the element formative layer connecting the element formative area to the outer peripheral part thereof; and
a process filling up the trenches with an insulator.

2. The production method of a semiconductor substrate as set forth in claim 1, wherein the trenches are enough deep to reach the buried insulating film, and are provided intermittently while a fixed distance exists between each two trenches adjacent to each other.

3. The production method of a semiconductor substrate as set forth in claim 2, wherein the fixed distance between the trenches is not less than 0.1 μm and not more than 1 μm.

4. The production method of a semiconductor substrate as set forth in claim 1, wherein the trenches are provided continuously along the outer perimeter of the element formative area while a fixed distance exists between the bottom surface of each of the trenches and the buried insulating film.

5. The production method of a semiconductor substrate as set forth in claim 4, wherein the fixed distance between the bottom surface of each of the trenches and the buried insulating film is not less than 0.1 μm and not more than 0.5 μm.

6. A semiconductor substrate constructed by laminating a support substrate, a buried insulating film and an element formative layer in this order and having a trench in the element formative layer for separating an element, comprising:
one or plural trenches formed in the element formative layer so as to connect an element formative area of the element formative layer to an outer peripheral part thereof at a part thereof at least.

7. The semiconductor substrate as set forth in claim 6, wherein the trenches are enough deep to reach the buried insulating film, and are provided intermittently while a fixed distance exists between each two trenches adjacent to each other.

8. The semiconductor substrate as set forth in claim 7, wherein the fixed distance between the trenches is not less than 0.1 μm and not more than 1 μm.

9. The semiconductor substrate as set forth in claim 6, wherein the trenches are provided continuously along the outer perimeter of the element formative area while a fixed distance exists between the bottom surface of each of the trenches and the buried insulating film.

10. The semiconductor substrate as set forth in claim 9, wherein the fixed distance between the bottom surface of each of the trenches and the buried insulating film is not less than 0.1 μm and not more than 0.5 μm.

11. A semiconductor device comprising the semiconductor substrate as set forth in one of claims 6 to 10.
